(19) United States
(12) Patent Application Publication
(10) Pub. No.: US 2024/0319595 A1
(43) Pub. Date: Sep. 26, 2024

(54) PHOTOREACTIVE POLYMER COMPOUND, PHOTORESIST COMPOSITION COMPRISING THE SAME, AND METHOD OF FORMING PATTERN BY USING THE PHOTORESIST COMPOUND

(71) Applicant: Samsung Electronics Co., Ltd., Suwon-si (KR)

(72) Inventors: Hoyoon PARK, Suwon-si (KR); Haengdeog KOH, Suwon-si (KR); Yoonhyun KWAK, Suwon-si (KR); Minsang KIM, Suwon-si (KR); Beomseok KIM, Suwon-si (KR); Hana KIM, Suwon-si (KR); Hyeran KIM, Suwon-si (KR); Chanjae AHN, Suwon-si (KR); Kyuhyun IM, Suwon-si (KR); Sungwon CHOI, Suwon-si (KR)

(73) Assignee: Samsung Electronics Co., Ltd., Suwon-si, (KR)

(21) Appl. No.: 18/612,246

(22) Filed: Mar. 21, 2024

(30) Foreign Application Priority Data
Mar. 24, 2023 (KR) 10-2023-0039263
May 16, 2023 (KR) 10-2023-0063280

(51) Int. Cl. G03F 7/039

(52) U.S. Cl. CPC G03F 7/039

(57) ABSTRACT

Provided are a photoreactive polymer compound including a first repeating unit represented by Formula 1 below, a photoresist composition including the same, and a method of forming a pattern by using the photoresist composition:

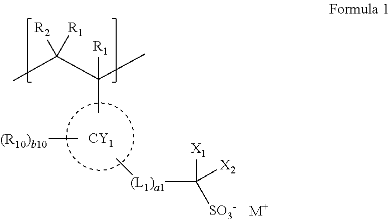

A description of Formula 1 is provided herein.

### CROSS-REFERENCE TO RELATED APPLICATION

This application is based on and claims priority under 35 U.S.C. § 119 to Korean Patent Application Nos. 10-2023-0039263, filed on Mar. 24, 2023, and 10-2023-0063280, filed on May 16, 2023 in the Korean Intellectual Property Office, the disclosures of each of which are incorporated by reference herein in their entirety.

### BACKGROUND

### 1. Field

The disclosure relates to a photoreactive polymer compound, a photoresist composition including the same, and a method of forming a pattern by using the photoresist composition.

### 2. Description of the Related Art

During the manufacturing of semiconductors, photoresists of which physical properties change in response to light are being used to form fine patterns. Among these photoresists, chemically amplified photoresists have been widely used. In chemically amplified photoresists, acids formed when light reacts with photoacid generators react again with base resins to change the solubility of the base resins in developing solutions, thereby enabling patterning.

However, in the case of a chemically amplified resist, a formed acid may diffuse to an unexposed region, which may cause a problem such as a reduction in uniformity of patterns or an increase in surface roughness. Although quenchers are sometimes used to solve such problems, the use of quenchers has a problem in that the dose required for exposure may increase.

Accordingly, there may be a need for a quencher which has improved dispersibility and/or improved compatibility with a base resin and is capable of effectively acting even when a small amount is used.

### SUMMARY

Provided are a photoreactive polymer compound having a short acid diffusion length (ADL) to be easy to prepare and have excellent etch resistance, a photoresist composition including the same, and a method of forming a pattern using the photoreactive polymer compound.

Additional aspects will be set forth in part in the description which follows and, in part, will be apparent from the description, or may be learned by practice of the presented embodiments of the disclosure.

According to an embodiment of the disclosure, a photoreactive polymer compound includes a first repeating unit represented by Formula 1 below:

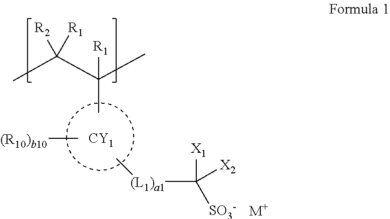

In Formula 1,
CY₁ may be a cyclic C₁-C₃₀ hydrocarbon group which may optionally include a hetero atom,
L₁ may be a single bond, or a divalent linking group which does not include oxygen, a1 may be 1, 2, 3, 4, 5, or 6, X₁ and X₂ may each independently be —F, or a linear, branched, or cyclic C₁-C₂₀ monovalent hydrocarbon group substituted with —F, R₁ to R₃ and R₁₀ may each independently be hydrogen, deuterium, a halogen, a cyano group, a hydroxy group, a linear, branched, or cyclic C₁-C₂₀ monovalent hydrocarbon group, which may optionally include a heteroatom, or —N(Q₁)(Q₂),
Q₁ and Q₂ may each independently be hydrogen, deuterium, or a linear, branched, or cyclic C₁-C₂₀ monovalent hydrocarbon group which may optionally include a heteroatom,
an adjacent two or more of R₁ to R₃ and R₁₀ may optionally be bonded to each other to form a cyclic C₁-C₃₀ hydrocarbon group which may optionally include a heteroatom,
b10 may be 1, 2, 3, 4, 5, 6, 7, 8, 9, or 10, and
M⁺ may be a counter cation.

According to an embodiment of the disclosure, a photoresist composition includes the photoreactive polymer compound.

According to an embodiment of the disclosure, a method of forming a pattern includes applying the above-described photoresist composition to form a photoresist film, exposing at least a portion of the photoresist film to high-energy rays to provide an exposed photoresist film, and developing the exposed photoresist film by using a developing solution.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a method of forming a pattern, according to an embodiment;

FIG. 2 shows side cross-sectional views illustrating a method of forming a pattern, according to an embodiment;

FIG. 3 is a graph showing a 1H-nuclear magnetic resonance (NMR) spectrum of a photoreactive polymer compound according to an embodiment;

FIG. 4 shows views illustrating a method of measuring an acid diffusion length (ADL);

FIG. 5 shows atomic force microscope (AFM) images observed when surface roughness (Rq) was measured;

FIGS. 6A to 6E are side cross-sectional views illustrating a method of forming a patterned structure according to an embodiment; and

FIGS. 7A to 7E are side cross-sectional views illustrating a method of forming a semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Since the disclosure can apply various transformations and have various embodiments, specific embodiments will be illustrated in the drawings and described in detail in the detailed description. However, it should be understood that this is not intended to limit the disclosure to specific embodiments, and includes all transformations, equivalents, and substitutes included in the spirit and scope of the disclosure. In describing the disclosure, when it is determined that the specific description of the known related art unnecessarily obscures the gist of the disclosure, the detailed description thereof will be omitted.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Hereinafter, unless explicitly described to the contrary, it is to be understood that the terms such as “including,” “having,” and “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

As used herein, “Cₓ-C_{y}” means that the number of carbon atoms constituting a substituent is in a range of x to y. For example, “C₁-C₆” means that the number of carbon atoms constituting a substituent is in a range of 1 to 6, and “C₆-C₂₀” means that the number of carbon atoms constituting a substituent is in a range of 6 to 20.

As used herein, the term “monovalent hydrocarbon group” may include, for example, linear or branched alkyl groups (for example, a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group), monovalent saturated cycloaliphatic hydrocarbon groups (for example, a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group), monovalent unsaturated aliphatic hydrocarbon groups (for example, an allyl group and a 3-cyclohexenyl), aryl groups (for example, a phenyl group, a 1-naphthyl group, and a 2-naphthyl group), arylalkyl groups (for example, a benzyl group and a diphenylmethyl group), and heteroatom-containing monovalent hydrocarbon groups (for example, a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group). In addition, in these groups, some hydrogen atoms may be substituted by a moiety including a heteroatom such as oxygen, sulfur, nitrogen, or halogen, or some carbon atoms may be replaced by a moiety including a heteroatom such as oxygen, sulfur, or nitrogen so that the groups may include a hydroxy group, a cyano group, a carbonyl group, a carboxyl group, an ether bond, an ester bond, a sulfonate ester bond, carbonate, a lactone ring, a sultone ring, a carboxylic anhydride moiety, or a haloalkyl moiety.

As used herein, the term “alkyl group” refers to a linear or branched saturated aliphatic hydrocarbon monovalent group, and specific examples thereof include a methyl group, an ethyl group, a propyl group, an isobutyl group, a sec-butyl group, a tert-butyl group, a pentyl group, an iso-amyl group, a hexyl group, and the like. As used herein, the term “alkylene group” refers to a linear or branched saturated aliphatic hydrocarbon divalent group, and specific examples thereof include a methylene group, an ethylene group, a propylene group, a butylene group, an isobutylene group, and the like.

As used herein, the term “halogenated alkyl group” refers to a group in which one or more substituents of an alkyl group are substituted with a halogen, and specific examples thereof include CF₃ and the like. Here, a halogen is F, Cl, Br, or I.

As used herein, the term “alkoxy group” refers to a monovalent group having a formula of —OA₁₀₁, wherein A₁₀₁ is an alkyl group. Specific examples thereof include a methoxy group, an ethoxy group, an isopropyloxy group, and the like.

As used herein, the term “cycloalkyl group” refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. As used herein, the term “cycloalkylene group” refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

As used herein, the term “cycloalkoxy group” refers to a monovalent group having a chemical formula of —OA₁₀₂, where A₁₀₂ is a cycloalkyl group. Specific examples thereof include a cyclopropoxy group, a cyclobutoxy group, and the like.

As used herein, the term “heterocycloalkyl group” may be a group in which some carbon atoms of a cycloalkyl group are replaced by a moiety including a hetero atom, for example, oxygen, sulfur, or nitrogen, and specifically, the heterocycloalkyl group may include an ether bond, an ester bond, a sulfonate ester bond, carbonate, a lactone ring, a sultone ring, or a carboxylic anhydride moiety. As used herein, the term “heterocycloalkylene group” is a group in which some carbon atoms of a cycloalkylene group are replaced by a moiety including a heteroatom, for example, oxygen, sulfur, or nitrogen.

As used herein, the term “alkenylene group” refers to a linear or branched unsaturated aliphatic hydrocarbon divalent group.

As used herein, the term “cycloalkenylene group” refers to a divalent unsaturated hydrocarbon cyclic group.

As used herein, the term “heterocycloalkenylene group” is a group in which some carbon atoms of the cycloalkenylene group are replaced by a moiety including a heteroatom, for example, oxygen, sulfur, or nitrogen.

As used herein, the term “aryl group” refers to a monovalent group having a carbocyclic aromatic system, and specific examples thereof include a phenyl group, a naphthyl group, an anthracenyl group, a phenanthrenyl group, a pyrenyl group, a chrysenyl group, and the like. As used herein, the term “arylene group” refers to a divalent group having a carbocyclic aromatic system.

As used herein, the term “heteroaryl group” refers to a monovalent group having a heterocyclic aromatic system, and specific examples thereof include a pyridinyl group, a pyrimidinyl group, a pyrazinyl group, and the like. As used herein, the term “heteroarylene group” refers to a divalent group having a heterocyclic aromatic system.

As used herein, the term “cycloalkyl group” refers to a monovalent, divalent, or trivalent group in which any hydrogen of the cycloalkyl group may be optionally further replaced by a binding site.

As used herein, the term “heterocycloalkyl group” refers to a monovalent, divalent, or trivalent group in which any hydrogen of the heterocycloalkyl group may be optionally further replaced by a binding site.

As used herein, the term “cycloalkenyl group” refers to a monovalent, divalent, or trivalent group in which any hydrogen of the cycloalkenyl group may be optionally further replaced by a binding site.

As used herein, the term “heterocycloalkenyl group refers to a monovalent, divalent, or trivalent group in which any hydrogen of the heterocycloalkenyl group may be optionally further replaced by a binding site.

As used herein, the term “aryl group” refers to a monovalent, divalent, or trivalent group in which any hydrogen of the aryl group may be optionally further replaced by a binding site.

As used herein, the term “heteroaryl group” refers to a monovalent, divalent, or trivalent group in which any hydrogen of the heteroaryl group may be optionally further replaced by a binding site.

As used herein, the term “counter cation” is any cation capable of ionic bonding with an anion and generally refers to a cation that prevents a compound from being charged.

Hereinafter, embodiments of the disclosure will be described in detail with reference to the accompanying drawings, wherein like reference numerals denote substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, embodiments set forth herein are merely examples and various changes may be made therein.

### [Photoreactive Polymer Compound]

A photoreactive polymer compound according to an embodiment may include a first repeating unit represented by Formula 1 below:

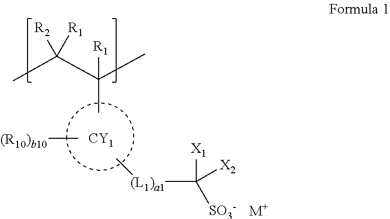

In Formula 1, CY₁ may be a cyclic C₁-C₃₀ hydrocarbon group may optionally include a heteroatom.

According to an embodiment, CY₁ may be a C₅-C₂₀ cycloalkyl group, a C₅-C₂₀ heterocycloalkyl group, a C₃-C₂₀ cycloalkenyl group, a C₃-C₂₀ heterocycloalkenyl group, a C₆-C₂₀ aryl group, or a C₁-C₂₀ heteroaryl group.

According to an embodiment, CY₁ may be a benzene group or a naphthalene group.

In Formula 1, L₁ may be a single bond, or a divalent linking group which does not include oxygen.

According to an embodiment, L₁ may be a C₁-C₂₀ alkylene group, a C₃-C₂₀ cycloalkylene group, a C₆-C₂₀ arylene group, or a C₃-C₂₀ heteroarylene group, unsubstituted or substituted with deuterium, a halogen, a C₁-C₂₀ alkyl group, or any combination thereof.

According to an embodiment, L₁ may be a C₁-C₂₀ alkylene group, a C₃-C₂₀ cycloalkylene group, a C₆-C₂₀ arylene group, or a C₃-C₂₀ heteroarylene group not including oxygen, unsubstituted or substituted with deuterium, a halogen, a C₁-C₂₀ alkyl group, or any combination thereof.

According to an embodiment, L₁ may be a C₁-C₂₀ alkylene group, a C₃-C₂₀ cycloalkylene group, or a C₆-C₂₀ arylene group, unsubstituted or substituted with deuterium, a halogen, a C₁-C₂₀ alkyl group, or any combination thereof.

According to an embodiment, L₁ may be a methylene group, an ethylene group, a propylene group, a butylene group, an isobutylene group, a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, a phenylene group, or a naphthylene group, unsubstituted or substituted with deuterium, a halogen, a C₁-C₂₀ alkyl group, or any combination thereof.

In Formula 1, a1 may be 1, 2, 3, 4, 5, or 6.

In Formula 1, a1 may denote the number of repetitions of L₁. When a1 is 2 or more, two or more Lis may be identical to or different from each other.

In Formula 1, X₁ and X₂ may each independently be —F, or a linear, branched, or cyclic C₁-C₂₀ monovalent hydrocarbon group substituted with —F.

According to an embodiment, X₁ and X₂ may each independently be —F, or a linear, branched, or cyclic C₁-C₂₀ monovalent perfluoroalkyl group substituted with —F.

According to an embodiment, X₁ and X₂ may each independently be —F, —CH₂F, —CHF₂, or —CF₃.

In Formula 1, R₁ to R₃ and R₁₀ may each independently be hydrogen, deuterium, a halogen, a cyano group, a hydroxy group, a linear, branched, or cyclic C₁-C₂₀ monovalent hydrocarbon group, which may optionally include a heteroatom, or —N(Q₁)(Q₂), Q₁ and Q₂ may each independently be hydrogen, deuterium, or a linear, branched, or cyclic C₁-C₂₀ monovalent hydrocarbon group which may optionally include a heteroatom, and an adjacent two or more of R₁ to R₃ and R₁₀ may be optionally bonded to each other to form a cyclic C₁-C₃₀ hydrocarbon group which may optionally include a heteroatom.

According to an embodiment, R₁ to R₃ and R₁₀ may each independently be a C₁-C₂₀ alkyl group, a C₃-C₂₀ cycloalkyl group, a C₁-C₂₀ heterocycloalkyl group, a C₆-C₂₀ aryl group, or a C₅-C₂₀ heteroaryl group, unsubstituted or substituted with hydrogen, deuterium, a halogen, a hydroxyl group, a C₁-C₂₀ alkyl group, a C₁-C₂₀ alkoxy group, a C₃-C₂₀ cycloalkyl group, a C₆-C₂₀ aryl group, a C₆-C₂₀ aryloxy group, a C₃-C₂₀ heteroaryl group, or any combination thereof.

In Formula 1, b10 may be 1, 2, 3, 4, 5, 6, 7, 8, 9, or 10.

In Formula 1, M⁺ may be a counter cation.

According to an embodiment, M⁺ may be a substituted or unsubstituted sulfonium cation, a substituted or unsubstituted iodonium cation, a substituted or unsubstituted selenium cation, a substituted or unsubstituted tellurium cation, a substituted or unsubstituted ammonium cation, a substituted or unsubstituted phosphonium cation, or any combination thereof.

According to an embodiment, M⁺ may be represented by any one of Formulas 2-1 to 2-3 below:

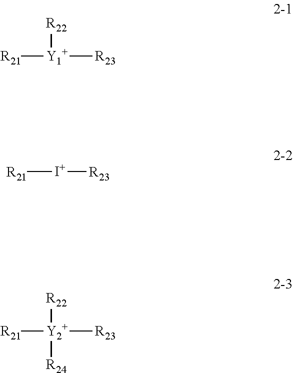

In Formulas 2-1 to 2-3, Y₁⁺ may be S⁺, Se⁺, or Te⁺, Y₂⁺ may be N⁺ or P⁺, R₂₁ to R₂₄ may each independently be a linear, branched, or cyclic C₁-C₃₀ monovalent hydrocarbon group which may optionally include a heteroatom, and an adjacent two of R₂₁ to R₂₄ may be optionally bonded to each other to form a ring.

According to an embodiment, M⁺ may be represented by any one of Formulas 2-11 to 2-13 below:

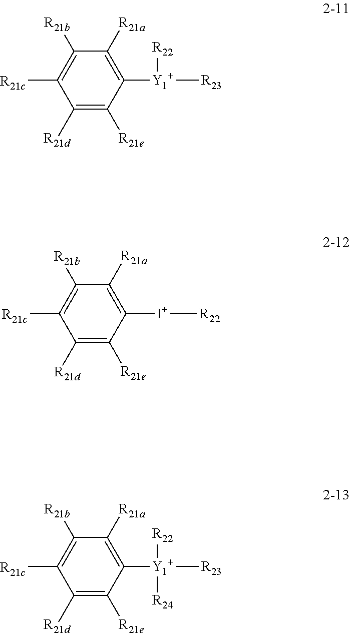

In Formulas 2-11 to 2-13, Y₁⁺, Y₂⁺, and R₂₂ to R₂₄ may be as defined herein, R₂₁ₐ to R₂₁ₑ may each independently be defined as for R₂₁, and an adjacent two of R₂₁ₐ to R₂₁ₑ and R₂₂ to R₂₄ may be optionally bonded to each other to form a ring.

According to an embodiment, M⁺ may be selected from Group I below:

### Group I

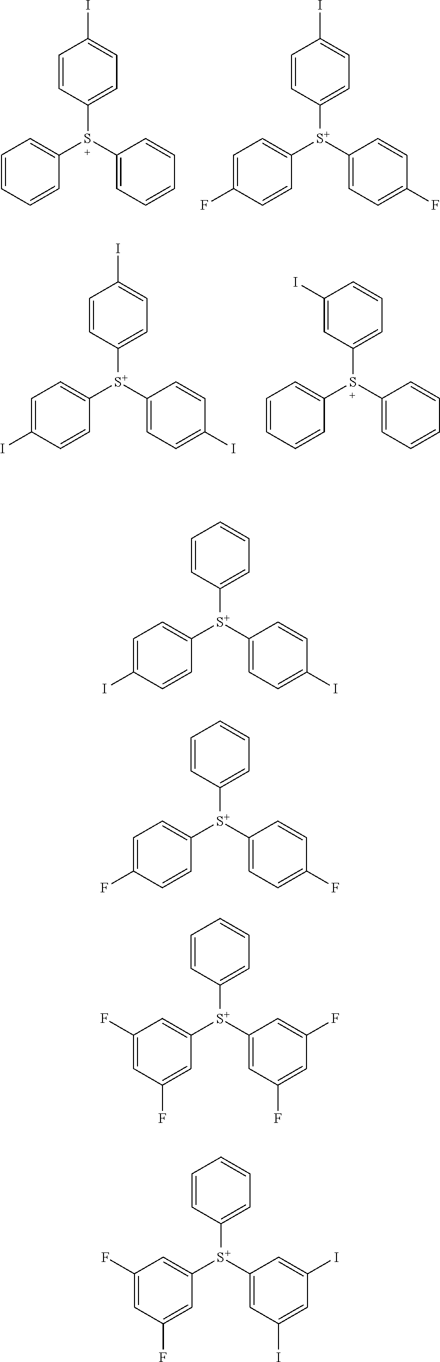

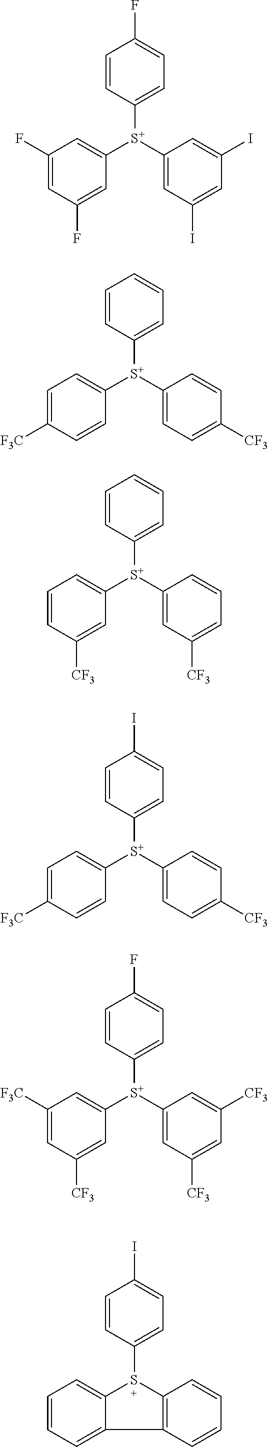

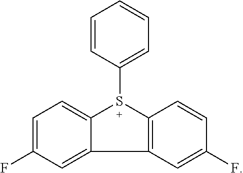

According to an embodiment, the repeating unit represented by Formula 1 may be represented by any one of Formulas 1-1 to 1-3 below:

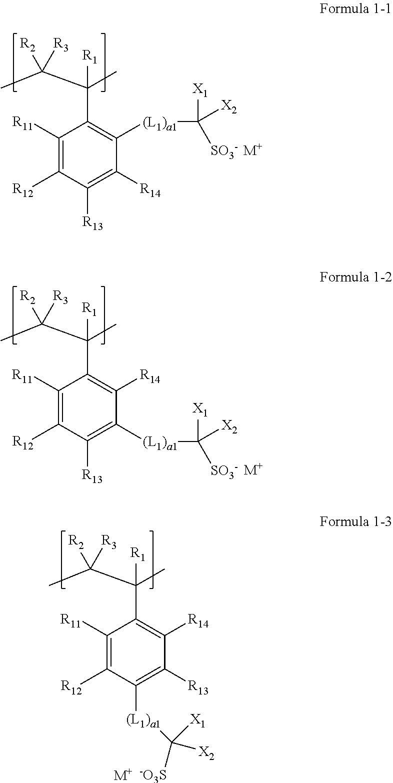

In Formulas 1-1 to 1-3, L₁, a1, X₁, X₂, R₁ to R₃, and M⁺ may be as defined herein, R₁₁ to R₁₄ may each independently be defined as for R₁₀ in Formula 1, and an adjacent two or more of R₁₁ to R₁₄ may be optionally bonded to each other to form a cyclic C₁-C₃₀ hydrocarbon group which may optionally include a heteroatom.

According to an embodiment, the first repeating unit may be a photoacid generating unit.

According to an embodiment, the photoreactive polymer compound may include (or consist of) the first repeating unit or may be a copolymer further including other repeating units.

According to an embodiment, the photoreactive polymer compound may be a copolymer further including a second repeating unit represented by Formula 4 below or a third repeating unit represented by Formula 5 below:

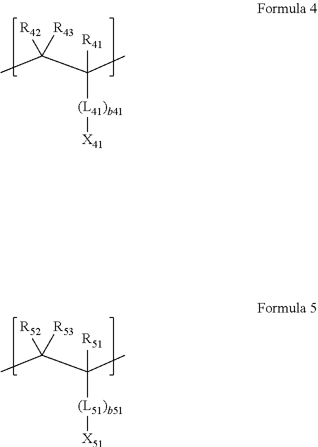

In Formulas 4 and 5, L₄₁ and L₅₁ may each independently be a single bond, a substituted or unsubstituted C₁-C₁₀ alkylene group, a substituted or unsubstituted C₃-C₁₀ cycloalkylene group, a substituted or unsubstituted C₃-C₁₀ heterocycloalkylene group, a substituted or unsubstituted C₃-C₁₀ cycloalkylene group, a substituted or unsubstituted phenylene group, a substituted or unsubstituted naphthylene group, *—O—**, *—C(═O)O—**, —OC(═O)—**, *—C(═O)NH—**, —NHC(═O)—**, or any combination thereof, b41 and b51 may each independently be 1, 2, 3, 4, 5, or 6, R₄₁ to R₄₃ and R₅₁ to R₅₃ may each independently be hydrogen, deuterium, a halogen, a cyano group, a hydroxy group, a linear, branched, or cyclic C₁-C₂₀ monovalent hydrocarbon group, which may optionally include a heteroatom, or —N(Q₁)(Q₂), X₄₁ may be hydrogen, deuterium, a halogen, a cyano group, a hydroxy group, a C₁-C₂₀ alkoxy group, a linear, branched, or cyclic C₁-C₂₀ monovalent hydrocarbon group, which may optionally include a heteroatom, or —N(Q₁)(Q₂), and X₅₁ may be an acid labile group.

According to an embodiment, the second repeating unit represented by Formula 4 may be a repeating unit represented by Formula 4-1 below:

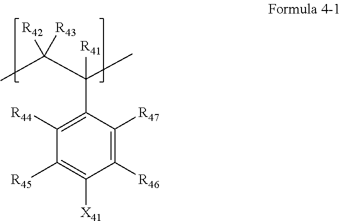

In Formula 4-1, R₄₁ to R₄₃ and X₄₁ may be as defined herein, and R₄₄ to R₄₇ may each independently be hydrogen, deuterium, a halogen, a cyano group, a hydroxy group, a C₁-C₂₀ alkoxy group, or a linear, branched, or cyclic C₁-C₂₀ monovalent hydrocarbon group which may optionally include a heteroatom.

According to an embodiment, X₄₁ may be a non-acid labile group.

According to an embodiment, the third repeating unit represented by Formula 5 may be a repeating unit represented by Formula 5-1:

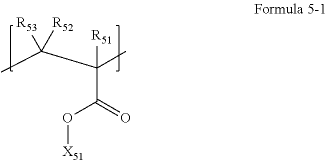

In Formula 5-1, R₅₁ to R₅₃ and X₅₁ may be as defined herein.

According to an embodiment, the acid labile group may be a group represented by any one of Formulas 6-1 to 6-12 below:

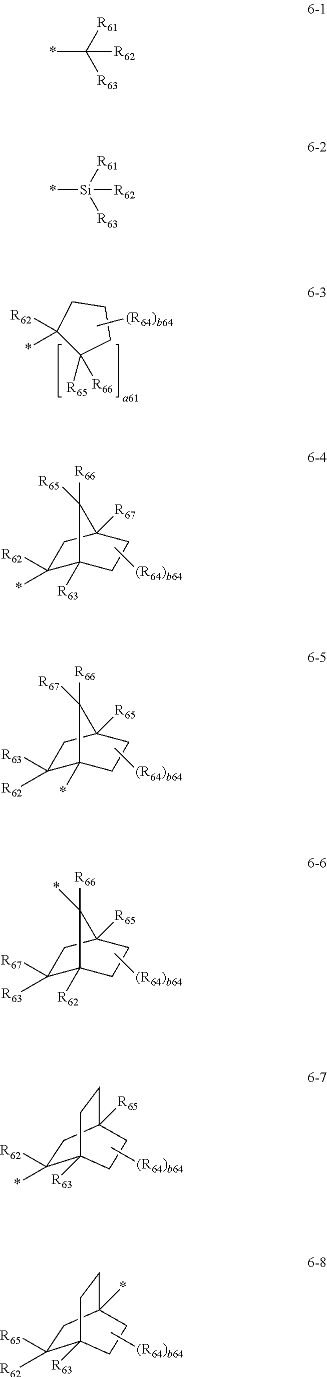

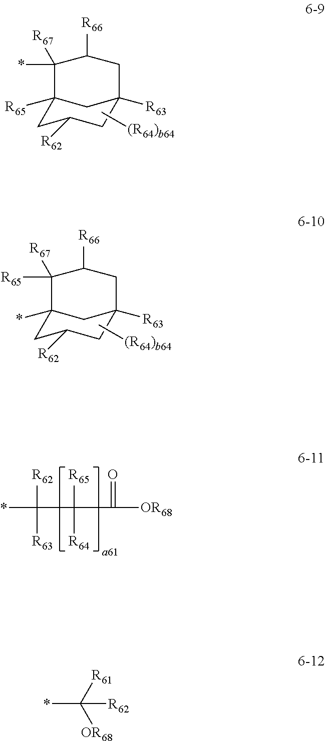

In Formulas 6-1 to 6-12, a61 may be an integer from 0 to 6, R₆₁ to R₆₇ may each independently be hydrogen, or a linear, branched, or cyclic C₁-C₂₀ monovalent hydrocarbon group which may optionally include a heteroatom, R₆₈ may be a linear, branched, or cyclic C₁-C₂₀ monovalent hydrocarbon group which may optionally include a heteroatom, two adjacent groups of R₆₁ to R₆₈ may be optionally bonded to each other to form a ring, b64 may be an integer from 0 to 6, and * may be a binding site with an adjacent atom.

According to an embodiment, the acid labile group may be selected from Group II below:

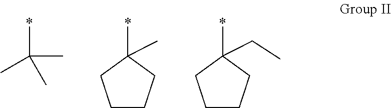

In Group II,
* may be a binding site with an adjacent atom.

According to an embodiment, the photoreactive polymer compound may be Polymer 1 below.

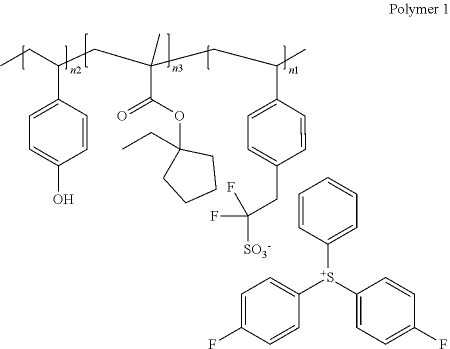

In Polymer 1, n1, n2, and n3 may each independently be an integer from 1 to 100,000.

Since the first repeating unit represented by Formula 1 satisfies a structure in which L₁ does not include oxygen, etch resistance may be improved, and since a photoacid generating group constitutes a portion of the photoreactive polymer compound, acid diffusion length (ADL) may be reduced. Accordingly, a photoresist composition according to an embodiment may have excellent characteristics such as improved developability and/or improved resolution.

According to an embodiment, the photoreactive polymer compound may include (or consist of) the first repeating unit represented by Formula 1 and the second repeating unit represented by Formula 4. For example, the photoreactive polymer compound may not include the third repeating unit represented by Formula 5.

According to an embodiment, the photoreactive polymer compound may include (or consist of) the first repeating unit represented by Formula 1 and the third repeating unit represented by Formula 5. For example, the photoreactive polymer compound may not include the second repeating unit represented by Formula 4.

According to an embodiment, the photoreactive polymer compound may include the first repeating unit represented by Formula 1, the second repeating unit represented by Formula 4, and the third repeating unit represented by Formula 5.

According to an embodiment, the photoreactive polymer compound may have a weight average molecular weight Mw of about 1,000 to about 1,000,000, about 2,000 to about 500,000, or about 3,000 to about 200,000 which is measured through gel permeation chromatography using a tetrahydrofuran solvent and polystyrene as standard materials.

According to an embodiment, a polydispersity index (PDI: Mw/Mn) of the photoreactive polymer compound may be in a range of about 1.0 to about 3.0, about 1.0 to about 2.5, or about 1.0 to about 2.0. When the above range is satisfied, the dispersibility and/or compatibility of the photoreactive polymer compound may be easy to control, and a possibility of foreign materials remaining on a pattern may be reduced, or the deterioration of a pattern profile may be minimized. Accordingly, the photoresist composition may be more suitable for forming a fine pattern.

The photoreactive polymer compound may be prepared through any suitable method and may be prepared, for example, by dissolving unsaturated bond-containing monomer(s) in an organic solvent, and then thermally polymerizing the unsaturated bond-containing monomer(s) in a radical initiator.

According to an embodiment, when the photoreactive polymer compound further includes the second repeating unit represented by Formula 4 and/or the third repeating unit selected from repeating units represented by Formula 5, a mole fraction (mol %) of each repeating unit derived from each monomer may be as follows, but one or more embodiments are not limited thereto: i) a mole fraction of the first repeating unit represented by Formula 1 may be in a range of about 1 mol % to about 80 mol %, about 2 mol % to about 70 mol %, about 5 mol % to about 50 mol %, or about 10 mol % to about 40 mol %, ii) a mole fraction of the second repeating unit represented by Formula 4 may be in a range of about 1 mol % to about 80 mol %, about 2 mol % to about 70 mol %, about 5 mol % to about 50 mol %, or about 10 mol % to about 40 mol %, and iii) a mole fraction of the third repeating unit represented by Formula 5 may be in a range of about 10 mol % to about 99 mol %, about 20 mol % to about 95 mol %, about 30 mol % to about 90 mol %, about 40 mol % to about 70 mol %, or about 50 mol % to about 60 mol %.

According to an embodiment, the photoreactive polymer compound may be a random copolymer, a block copolymer, an alternating copolymer, a graft copolymer, or any combination thereof which includes the first repeating unit and includes the second repeating unit and/or the third repeating unit.

The structure (composition) of the photoreactive polymer compound may be identified by performing Fourier transform infrared (FT-IR) analysis, nuclear magnetic resonance (NMR) analysis, fluorescence X-ray (XRF) analysis, mass spectrometry, ultraviolet (UV) analysis, single crystal X-ray structure analysis, powder X-ray diffraction (PXRD) analysis, liquid chromatography (LC) analysis, size exclusion chromatography (SEC) analysis, thermal analysis, or the like. A detailed identification method is as described in Examples.

### [Photoresist Composition]

According to an aspect, provided is a photoresist composition including the photoreactive polymer compound.

In general, the roughness of a surface of a photoresist film after development may increase due to a difference in ADL in a photoresist composition. Since the photoresist composition according to an embodiment includes the photoreactive polymer compound including the first repeating unit represented by Formula 1, etch resistance may be excellent, and an ADL may be reduced, thereby improving the surface roughness of a photoresist film. Accordingly, the photoresist composition according to an embodiment may have excellent characteristics such as improved developability and/or improved resolution.

The solubility of the photoresist composition in a developing solution may be changed by exposure to high-energy rays. The photoresist composition may be a positive photoresist composition in which an exposed portion of a photoresist film is dissolved and removed to form a positive photoresist pattern, or a negative photoresist composition in which an unexposed portion of a photoresist film is dissolved and removed to form a negative photoresist pattern. In addition, a sensitive photoresist composition according to an embodiment may be for an alkali developing process in which an alkali developing solution is used for a developing process when a photoresist pattern is formed and may also be for a solvent developing process in which an organic solvent-containing developing solution (hereinafter referred to as an organic developing solution) is used for the developing process.

According to an embodiment, a content of the photoreactive polymer compound may be in a range of about 0.01 parts by weight to about 99 parts by weight with respect to about 100 parts by weight of the photoresist composition. For example, the content of the photoreactive polymer compound may be in a range of about 0.05 parts by weight to about 70 parts by weight, about 0.1 parts by weight to about 50 parts by weight, about 0.5 parts by weight to about 40 parts by weight, about 1 part by weight to about 20 parts by weight, or about 2 parts by weight to about 10 parts by weigh with respect to about 100 parts by weight of the photoresist composition.

When the content of the photoreactive polymer compound in the photoresist composition satisfies the above range, photoacid generation may be maintained at an appropriate level, and for example, any performance loss caused by the formation of foreign particles due to a decrease in sensitivity and/or lack of solubility may be reduced.

According to an embodiment, the photoresist composition may include a photoacid generator.

According to an embodiment, the photoacid generator may include (or consist of) the photoreactive polymer compound. That is, the photoreactive polymer compound may serve as a photoacid generator in the photoresist composition, and the photoresist composition may not include a separate photoacid generator other than the photoreactive polymer compound.

According to an embodiment, the photoresist composition may further include at least one of an organic solvent, a base resin, and a photodegradable quencher (PDQ).

According to an embodiment, the photoresist composition may not further include a base resin. That is, the photoreactive polymer compound may serve as a base resin in the photoresist composition, and the photoresist composition may not include a separate base resin other than the photoreactive polymer compound.

The photoresist composition according to an embodiment may include the photoreactive polymer compound including the first repeating unit represented by Formula 1 and thus may not include a separate photoacid generator or base resin. In addition, since the first repeating unit represented by Formula 1 satisfies a structure in which L₁ does not include oxygen, etch resistance may be improved, and since a photoacid generating group constitutes a portion of the photoreactive polymer compound, an ADL may be reduced. Accordingly, the photoresist composition according to an embodiment may have excellent characteristics such as improved developability and/or improved resolution.

Since the photoreactive polymer compound is as described above, the organic solvent, the base resin, the photoacid generator, and any components contained as necessary will be described below. In addition, as the photoreactive polymer compound which is used in the photoresist composition and includes the repeating unit represented by Formula 1, one type of a photoreactive polymer compound may be used, or two or more different types of photoreactive polymer compounds may be used in combination.

### <Organic Solvent>

An organic solvent included in the photoresist composition is not particularly limited as long as the organic solvent is capable of dissolving or dispersing a photoreactive polymer compound, a base resin, a photoacid generator, and any components contained as necessary. As the organic solvent, one type of an organic solvent may be used, or two or more different types of organic solvents may be used in combination. In addition, a mixed solvent in which water and an organic solvent are mixed may be used.

Examples of the organic solvent may include, for example, an alcohol-based solvent, an ether-based solvent, a ketone-based solvent, an amide-based solvent, an ester-based solvent, a sulfoxide-based solvent, a hydrocarbon-based solvent, and the like.

More specifically, examples of the alcohol-based solvent may include a monoalcohol-based solvent such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, or diacetone alcohol, a polyhydric alcohol-based solvent such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, or tripropylene glycol, and a polyhydric alcohol-containing ether-based solvent such as ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, diethylene glycol dimethyl ether, propylene glycol monomethyl ether, propylene glycol dimethyl ether, propylene glycol monoethyl ether, propylene glycol monopropyl ether, propylene glycol monobutyl ether, dipropylene glycol monomethyl ether, dipropylene glycol monoethyl ether, or dipropylene glycol monopropyl ether.

Examples of the ether-based solvent may include a dialkyl ether-based solvent such as diethyl ether, dipropyl ether, or dibutyl ether, a cyclic ether-based solvent such as tetrahydrofuran (THF) or tetrahydropyran, and an aromatic ring-containing ether-based solvent such as diphenyl ether or anisole.

Examples of the ketone-based solvent may include a chain ketone-based solvent such as acetone, methyl ethyl ketone, methyl n-propyl ketone, methyl n-butyl ketone, diethyl ketone, methyl iso-butyl ketone, 2-heptanone, ethyl-n-butyl ketone, methyl-n-hexyl ketone, diisobutyl ketone, or trimethylnonanone, a cyclic ketone-based solvent such as cyclopentanone, cyclohexanone, cycloheptanone, cyclooctanone, or methylcyclohexanone, 2,4-pentanedione, acetonyl acetone, and acetophenone.

Examples of the amide-based solvent may include a cyclic amide-based solvent such as N,N′-dimethylimidazolidinone or N-methyl-2-pyrrolidone, and a chain amide-based solvent such as N-methylformamide, N,N-dimethylformamide, N,N-diethylformamide, acetamide, N-methylacetamide, N,N-dimethylacetamide, or N-methylpropionamide.

Examples of the ester-based solvent may include an acetate ester-based solvent such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, or n-nonyl acetate, a polyhydric alcohol-containing ether carboxylate-based solvent such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, or dipropylene glycol monoethyl ether acetate, a lactone-based solvent such as γ-butyrolactone or δ-valerolactone, a carbonate-based solvent such as dimethyl carbonate, diethyl carbonate, ethylene carbonate, or propylene carbonate, a lactate ester-based solvent such as methyl lactate, ethyl lactate, n-butyl lactate, or n-amyl lactate, glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and diethyl phthalate.

Examples of the sulfoxide-based solvent may include dimethyl sulfoxide, diethyl sulfoxide, and the like.

Examples of the hydrocarbon-based solvent may include an aliphatic hydrocarbon-based solvent such as n-pentane, isopentane, n-hexane, isohexane, n-heptane, isoheptane, 2,2,4-trimethylpentane, n-octane, isooctane, cyclohexane, or methylcyclohexane, and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, or n-amylnaphthalene.

Specifically, the organic solvent may be selected from an alcohol-based solvent, an amide-based solvent, an ester-based solvent, a sulfoxide-based solvent, and any combination thereof. More specifically, the organic solvent may be selected from propylene glycol monomethyl ether, propylene glycol monoethyl ether, propylene glycol monomethyl ether acetate, N-methyl-2-pyrrolidone, N,N-dimethylacetamide, ethyl lactate, dimethyl sulfoxide, and any combination thereof.

Meanwhile, when an acid labile group in the form of acetal is used, in order to accelerate a deprotection reaction of acetal, high-boiling alcohol such as diethylene glycol, propylene glycol, glycerol, 1,4-butanediol, or 1,3-butanediol may be further added to the organic solvent.

The organic solvent may be used in a range of about 200 parts by weight to about 5,000 parts by weight, specifically, about 400 parts by weight to about 3,000 parts by weight, with respect to about 100 parts by weight of the base resin.

### <Base Resin>

According to an embodiment, the photoresist composition may further include a base resin different from the photoreactive polymer compound.

The base resin may include a repeating unit which includes an acid labile group and is represented by Formula 5 below:

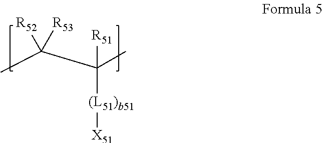

In Formula 5, R₅₁, L₅₁, a51, and X₅₁ may be as defined above.

The base resin including the repeating unit represented by Formula 5 may be decomposed under the action of an acid to generate a carboxyl group, thereby being converted to be alkali soluble.

In addition to the repeating unit represented by Formula 5, the base resin may further include a repeating unit represented by Formula 4 below:

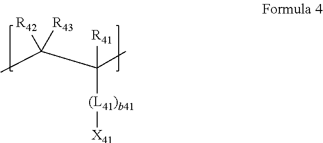

In Formula 4, R₄₁, L₄₁, a51, and X₄₁ may be as defined above.

For example, in an ArF lithography process, X₄₁ may include a lactone ring as a polar moiety, and in a KrF, electron beam (EB), or extreme ultraviolet (EUV) lithography process, X₄₁ may be phenol.

According to an embodiment, the base resin may not include a moiety including an anion and/or a cation.

The base resin may have a weight average molecular weight Mw of about 1,000 to about 500,000, specifically, about 3,000 to about 100,000 which is measured through gel permeation chromatography using a THF solvent and polystyrene as standard materials.

The PDI (Mw/Mn) of the base resin may be in a range of about 1.0 to about 3.0, specifically, about 1.0 to about 2.0. When the above range is satisfied, a possibility of foreign materials remaining on a pattern may be lowered, or the deterioration of a pattern profile may be minimized. Accordingly, the photoresist composition may be more suitable for forming a fine pattern.

The base resin may be prepared through any suitable method and may be prepared, for example, by dissolving unsaturated bond-containing monomer(s) in an organic solvent, and then heat-polymerizing the unsaturated bond-containing monomer(s) in a radical initiator.

In the base resin, a mole fraction (mol %) of each repeating unit derived from each monomer may be as follows, but one or more embodiments are not limited thereto: i) a mole fraction of the repeating unit represented by Formula 5 may be in a range of about 1 mol % to about 60 mol %, about 5 mol % to about 50 mol %, or about 10 mol % to about 50 mol %, and ii) a mole fraction of the repeating unit represented by Formula 4 may be in a range of about 40 mol % to about 99 mol %, about 50 mol % to about 95 mol %, or about 50 mol % to about 90 mol %.

The base resin may be a single polymer or may include a mixture of two or more types of polymers having different compositions, weight average molecular weights, and/or PDIs.

### <Photoacid Generator>

According to one embodiment, in addition to the photoreactive polymer compound, the photoresist composition may further include other photoacid generators.

The photoacid generator may be any compound capable of generating an acid when exposed to high-energy rays such as UV rays, deep UV (DUV) rays, EBs, EUV rays, X-rays, excimer lasers, or γ-rays.

The photoacid generator may include at least one of a sulfonium salt, an iodonium salt, and a combination thereof.

According to an embodiment, the photoacid generator may be represented by Formula 7 below:

B₇₁⁺A₇₁⁻ Formula 7

In Formula 7, B₇₁⁺ may be represented by Formula 7A below, A₇₁⁻ may be represented by any one of Formulas 7B to 7D below, and B₇₁⁺ and A₇₁⁻ may be optionally linked through a carbon-carbon covalent bond:

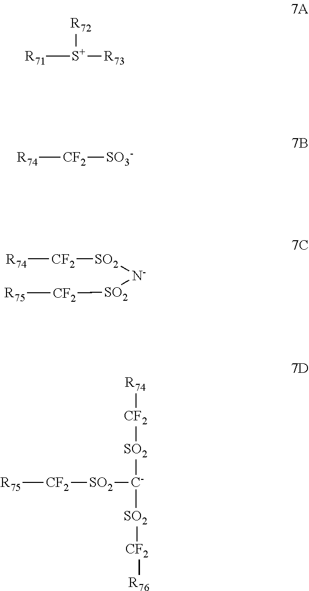

In Formulas 7A to 7D, R₇₁ to R₇₃ may each independently be a linear, branched, or cyclic C₁-C₂₀ monovalent hydrocarbon group, an adjacent two of R₇₁ to R₇₃ may be optionally bonded to each other to form a ring, and R₇₄ to R₇₆ may each independently be F, or a linear, branched, or cyclic C₁-C₂₀ monovalent hydrocarbon group which may optionally include a hetero atom.

R₇₁ to R₇₃ in Formula 7A may be defined as for R₃₁ to R₃₅ in Formula 3-1.

In the descriptions of R₇₄ to R₇₆ in Formulas 7B to 7D, examples of the monovalent hydrocarbon group may include linear or branched alkyl groups (for example, a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosanyl group), monovalent saturated cycloaliphatic hydrocarbon groups (for example, a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group), monovalent unsaturated aliphatic hydrocarbon groups (for example, an allyl group and a 3-cyclohexenyl), aryl groups (for example, a phenyl group, a 1-naphthyl group, and a 2-naphthyl group), arylalkyl groups (for example, a benzyl group and a diphenylmethyl group), and heteroatom-containing monovalent hydrocarbon groups (for example, a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group). In addition, in these groups, some hydrogen atoms may be substituted by a moiety including a heteroatom such as oxygen, sulfur, nitrogen, or halogen, or some carbon atoms may be replaced by a moiety including a heteroatom such as oxygen, sulfur, or nitrogen so that the groups may include a hydroxy group, a cyano group, a carbonyl group, a carboxyl group, an ether bond, an ester bond, a sulfonate ester bond, carbonate, a lactone ring, a sultone ring, a carboxylic anhydride moiety, or a haloalkyl moiety.

For example, in Formula 7, B71+ may be represented by Formula 7A, and A₇₁⁻ may be represented by Formula 7B. Specifically, in Formula 7A, R₇₁ to R₇₃ may each be a phenyl group, and in Formula 7B, R₇₄ may be a propyl group substituted with F.

The photoacid generator may be included in a range of about 0 parts by weight to about 40 parts by weight, about 0.1 parts by weight to about 40 parts by weight, or about 0.1 parts by weight to about 20 parts by weight with respect to about 100 parts by weight of the base resin. When the above range is satisfied, appropriate resolution may be achieved, and problems related to foreign material particles after development or during stripping may be reduced.

As the photoacid generator, one type of a photoacid generator may be used, or two or more different types of photoacid generators may be mixed and used.

### <PDQ>

The PDQ may be a salt that generates an acid having weaker acidity than an acid generated from the photoreactive polymer compound and/or the photoacid generator.

The PDQ may include an ammonium salt, a sulfonium salt, an iodonium salt, and a combination thereof.

In an embodiment, the PDQ may be represented by Formula 8 below:

B₈₁⁺A₈₁⁻ Formula 8

In Formula 8, B₈₁⁺ may be represented by any one of Formulas 8A to 8C below, A₈₁⁻ may be represented by any one of Formulas 8D to 8F below, and B₈₁⁺ and A₈₁⁻ may be optionally linked through a carbon-carbon covalent bond:

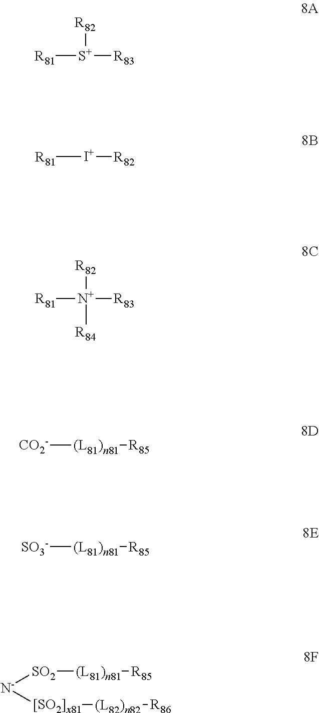

In Formulas 8A to 8F, L₈₁ and L₈₂ may each independently be a single bond or CRR′, R and R′ may each independently be hydrogen, deuterium, a halogen, a cyano group, a hydroxyl group, a C₁-C₂₀ alkyl group, a C₁-C₂₀ halogenated alkyl group, a C₁-C₂₀ alkoxy group, a C₃-C₂₀ cycloalkyl group, or a C₃-C₂₀ cycloalkoxy group, n81 and n82 may each independently be 1, 2, or 3, x81 may be 0 or 1, R₈₁ to R₈₄ may each independently be a linear, branched, or cyclic C₁-C₂₀ monovalent hydrocarbon group, an adjacent two of R₈₁ to R₈₄ may be optionally bonded to each other to form a ring, and R₈₅ and R₈₆ may each be hydrogen, a halogen, or a linear, branched, or cyclic C₁-C₂₀ monovalent hydrocarbon group which may optionally include a heteroatom.

The PDQ may be included in a range of about 0.001 parts by weight to about 20 parts by weight, about 0.005 parts by weight to about 10 parts by weight, about 0.01 parts by weight to about 5 parts by weight, about 0.05 parts by weight to about 2 parts by weight, about 0.1 parts by weight to about 1 part by weight, or about 0.2 parts by weight to about 0.5 parts by weight with respect to about 100 parts by weight of the photoresist composition. When the above range is satisfied, appropriate resolution may be achieved, and problems related to foreign material particles after development or during stripping may be reduced.

As the PDQ, one type of a PDQ may be used, or two or more different types of PDQs may be mixed and used.

### <Any Components>

The photoresist composition may further include a surfactant, a crosslinking agent, a leveling agent, a colorant, or any combination thereof as necessary.

The photoresist composition may further include a surfactant to improve coatability, developability, and the like. A specific example of the surfactant may include, for example, a nonionic surfactant such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, or polyethylene glycol distearate. As the surfactant, a commercially available product or a synthetic product may be used. Examples of the commercially available product of the surfactant may include KP341 (manufactured by Shin-Etsu Chemical Co., Ltd.), Polyflow No. 75 and Polyflow No. 75 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (products manufactured by DIC Corporation), FLUORAD™ FC430 and FLUORAD™ FC431 (manufactured by Sumitomo 3M, Ltd.), Asahi Guard™ AG710 (manufactured by AGC Seimi Chemical Co., Ltd.), and SURFLON™ S-382, SURFLON™ SC-101, SURFLON™ SC-102, SURFLON™ SC-103, SURFLON™ SC-104, SURFLON™ SC-105, and SURFLON™ SC-106 (manufactured by AGC Seimi Chemical Co., Ltd.).

The surfactant may be included in a range of about 0 parts by weight to about 20 parts by weight with respect to about 100 parts by weight of the base resin. As the surfactant, one type of a surfactant may be used, or two or more different types of surfactants may be mixed and used.

A method of preparing the photoresist composition is not particularly limited, and for example, a method of mixing a photoreactive polymer compound, a base resin, a photoacid generator, and any components added as necessary in an organic solvent may be used. A temperature or time during mixing is not particularly limited. If necessary, filtration may be performed after mixing.

### [Method of Forming Pattern]

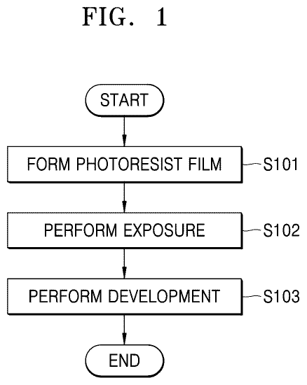

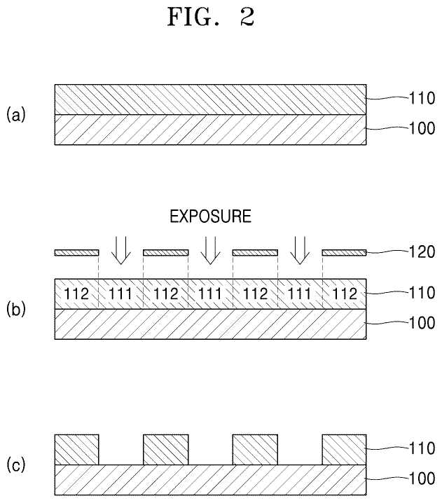

Hereinafter, a method of forming a pattern according to an embodiment will be described in more detail with reference to FIGS. 1 and 2. FIG. 1 is a flowchart illustrating the method forming a pattern method according to an embodiment, and FIG. 2 shows side cross-sectional views illustrating the method of forming a pattern according to an embodiment. Hereinafter, an example of the method of forming a pattern by using a positive photoresist composition will be described in detail, but one or more embodiments are not limited thereto.

Referring to FIG. 1, the method of forming a pattern may include operation S101 of applying a photoresist composition to form a photoresist film, operation S102 of exposing at least a portion of the resist film to high-energy rays, and operation S103 of developing the exposed photoresist film by using a developing solution. Such operations may be omitted if necessary or may be performed in a different order.

Referring to FIG. 2, first, a substrate 100 may be prepared. The substrate 100 may include, for example, a semiconductor substrate such as a silicon substrate or a germanium substrate, glass, quartz, ceramic, or copper. In some embodiments, the substrate 100 may include a Group III-V compound such as GaP, GaAs, GaSb, or the like.

A photoresist composition may be applied to a desired thickness on the substrate 100, specifically, through a coating method, to form a photoresist film 110. If necessary, heating may be performed to remove an organic solvent remaining in the photoresist film 110. As the coating method, spin coating, dipping, roller coating, or other general coating methods may be used. Among the coating methods, spin coating may be particularly used, and the viscosity, concentration, and/or spin speed of the photoresist composition may be adjusted to form the photoresist film 110 having a desired thickness. Specifically, the photoresist film 110 may have a thickness of about 10 nm to about 300 nm. More specifically, the photoresist film 110 may have a thickness of about 30 nm to about 200 nm.

A lower limit of a temperature of pre-bake may be 60° C. or more, specifically, 80° C. or more. In addition, an upper limit of the temperature of the pre-bake may be about 150° C. or less, specifically, about 140° C. or less. A lower limit of a time of the pre-bake may be 5 seconds or more, specifically, 10 seconds or more. An upper limit of the time of the pre-bake may be 600 seconds or less, specifically, 300 seconds or less.

Before the applying of the photoresist composition onto the substrate 100, an etching target film (not shown) may be further formed on the substrate 100. The etching target film may refer to a layer on which an image is transferred from a photoresist pattern and converted into a certain pattern. In an embodiment, the etching target film may be formed to include, for example, an insulating material such as silicon oxide, silicon nitride, or silicon oxynitride. In some embodiments, the etching target film may be formed to include a conductive material such as a metal, metal nitride, metal silicide, or metal silicide nitride. In some embodiments, the etching target film may be formed to include a semiconductor material such as polysilicon.

In an embodiment, an antireflection film may be further formed on the substrate 100 to maximize the efficiency of a photoresist. The antireflection film may be an organic or inorganic antireflection film.

In an embodiment, a protective film may be further provided on the photoresist film 110 to reduce the influence of alkaline impurities or the like included during a process. When immersion exposure is performed, for example, a protective film for immersion may also be provided on the photoresist film 110 to avoid direct contact between an immersion medium and the photoresist film 110.

Next, at least a portion of the photoresist film 110 may be exposed to high-energy rays. For example, high-energy rays passing through a mask 120 may be irradiated onto at least a portion of the resist film 110. For this reason, the photoresist film 110 may have an exposed portion 111 and an unexposed portion 112.

In some cases, the exposure may be performed by irradiating high-energy rays through a mask with a certain pattern by using a liquid such as water as a medium. Examples of the high-energy rays may include electromagnetic waves such as UV rays, DUV rays, EUV rays (with a wavelength of 13.5 nm), X-rays, and γ-rays, and charged particle beams such as EBs and a rays, and the like. Irradiating the high-energy rays may be collectively referred to as “exposure.”

Examples of an exposure light source may include various light sources such as a light source that emits laser light in a UV region, such as a KrF excimer laser (with a wavelength of 248 nm), an ArF excimer laser (with a wavelength of 193 nm), or an F2 excimer laser (with a wavelength of 157 nm), a light source that converts a wavelength of laser light from a solid-state laser light source (yttrium aluminum garnet (YAG) or semiconductor laser or the like) to emit harmonic laser light in a far UV or vacuum UV region, and a light source that irradiates EBs or EUV rays. During exposure, the exposure may be usually performed through a mask corresponding to a desired pattern, but when exposure light is an EB, the exposure may be performed through direct writing without using a mask.

Regarding an integral dose of high-energy rays, for example, when EUV rays are used as the high-energy rays, the integral dose may be 2,000 mJ/cm² or less, specifically, 500 mJ/cm² or less. In addition, when EBs are used as the high-energy rays, the integral dose may be 5,000 μC/cm² or less, specifically, 1,000 μC/cm² or less.

In addition, post-exposure bake (PEB) may be performed after the exposure. A lower limit of a temperature of the PEB may be 50° C. or more, specifically, 80° C. or more. An upper limit of the temperature of the PEB may be 180° C. or less, specifically, 130° C. or less. A lower limit of a time of the PEB may be 5 seconds or more, specifically, 10 seconds or more. An upper limit of the time of the PEB may be 600 seconds or less, specifically, 300 seconds or less.

Next, the exposed photoresist film 110 may be developed by using a developing solution. The exposed portion 111 may be washed away by the developing solution, and the unexposed portion 112 may remain unwashed away by the developing solution.

Examples of the developing solution may include an alkaline developing solution and a developing solution including an organic solvent (hereinafter also referred to as “organic developing solution”). Examples of a developing method may include a dipping method, a puddle method, a spray method, a dynamic injection method, and the like. A developing temperature may be, for example, 5° C. or more and 60° C. or less, and a developing time may be, for example, 5 seconds or more and 300 seconds or less.

The alkaline developing solution may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethylammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkali developing solution may further include a surfactant.

A lower limit of a content of the alkaline compound in the alkali developing solution may be 0.1 wt % or more, specifically, 0.5 wt % or more, and more specifically, 1 wt % or more. In addition, an upper limit of the content of the alkaline compound in the alkaline developing solution may be 20 wt % or less, specifically, 10 wt % or less, and more specifically, 5 wt % or less.

After development, the photoresist pattern may be cleaned with ultrapure water, and then water remaining on the substrate 100 and the photoresist pattern may be removed.

Examples of the organic solvent included in the organic developing solution may include the same organic solvents as described in the organic solvent.

A lower limit of a content of the organic solvent in the organic developing solution may be 80 wt % or more, specifically, 90 wt % or more, more specifically, 95 wt % or more, or particularly, 99 wt % or more.

The organic developing solution may also include a surfactant. In addition, a trace amount of water may be included in the organic developing solution. Furthermore, during development, the development may be stopped by substituting the organic developing solution with a solvent that is a different type therefrom.

The photoresist pattern after the development may be further cleaned.

Ultrapure water, a rinse solution, or the like may be used as a cleaning solution. A rinse solution is not particularly limited as long as the rinse solution does not dissolve a photoresist pattern, and a solution including a general organic solvent may be used. For example, the rinse solution may be an alcohol-based solvent or an ester-based solvent. After the cleaning, the rinse solution remaining on the substrate 100 and the photoresist pattern may be removed. In addition, when the ultrapure water is used, water remaining on the substrate 100 and the photoresist pattern may be removed.

In addition, developing solutions may be used singly or in a combination of two or more.

After the photoresist pattern is formed as described above, a pattern interconnection substrate may be obtained through etching. The etching may be performed through a known method including dry etching using a plasma gas and wet etching using an alkaline solution, a cupric chloride solution, a ferric chloride solution, or the like.

After the photoresist pattern is formed, plating may be performed. The plating is not particularly limited, and examples thereof may include copper plating, solder plating, nickel plating, gold plating, and the like.

The photoresist pattern remaining after the etching may be peeled off with an organic solvent. One or more embodiments are not limited thereto, but examples of such an organic solvent may include propylene glycol monomethyl ether acetate (PGMEA), propylene glycol monomethyl ether (PGME), ethyl lactate (EL), and the like. A peeling method is not particularly limited, but examples thereof may include an immersion method, a spray method, and the like. In addition, the pattern interconnection substrate on which the photoresist pattern is formed may be a multilayer interconnection substrate or may have small-diameter through-holes.

In an embodiment, the pattern interconnection substrate may be formed through a method of forming a photoresist pattern, depositing a metal in a vacuum, and then melting the photoresist pattern with a solution, that is, a lift-off method.

The disclosure will be described in more detail using the following Examples and Comparative Examples, but the technical scope of inventive concepts in the present disclosure is not limited only to the following Examples.

### EXAMPLES

### Synthesis Example 1: Synthesis of Polymer 1

### (1) Synthesis of Monomer A

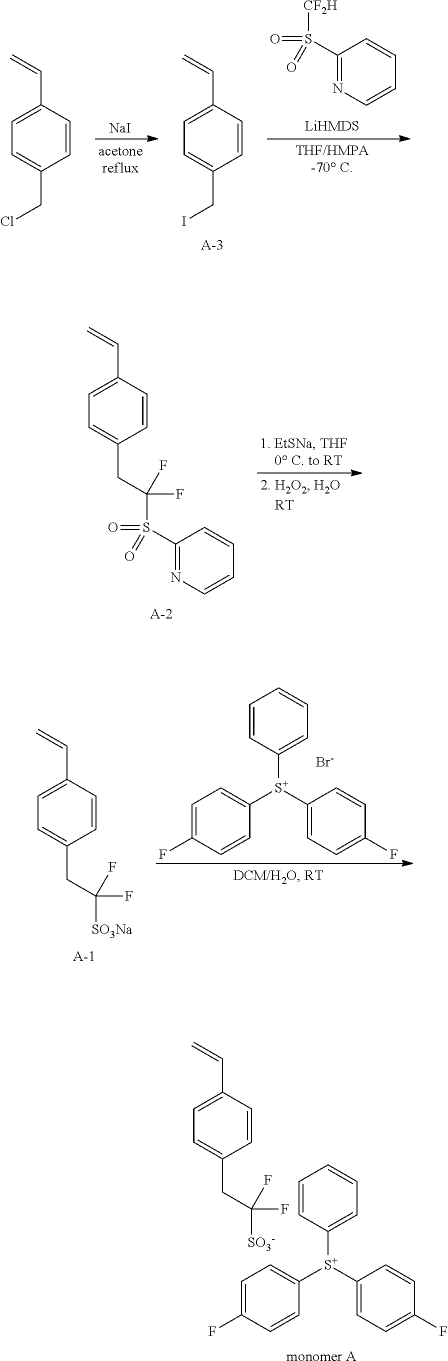

### Synthesis of Compound A-3

4-vinylbenzyl chloride (20.0 g, 131 mmol) and sodium iodide (58.5 g, 390 mmol) were put into a round bottom flask (RBF), mixed with 200 mL of acetone, and then stirred under reflux for 20 hours. Thereafter, a reaction solvent was removed by distillation under reduced pressure, and then water was added to extract an organic material with dichloromethane (DCM). An obtained organic layer was cleaned with an aqueous Na₂S₂O₃ solution, dried with MgSO₄, and filtered. The residue obtained by depressurizing and concentrating a filtered filtrate was separated and purified through silica gel column chromatography to obtain Compound A-3 (22.7 g, 71%). A generated compound was confirmed through nuclear magnetic resonance (NMR).

1H NMR (500 MHZ, CDCl₃) δ 7.33 (s, 4H), 6.68 (dd, 1H), 5.75 (d, 1H), 5.26 (d, 1H), 4.46 (s, 2H)

### Synthesis of Compound A-2

After Compound A-3 (15.0 g, 61.5 mmol) and 2-PySO₂CF₂H (24.7 g, 128 mmol) were put into an RBF and dissolved in a mixed solution of 450 mL of THF and 45 mL of hexamethylphosphoramide (HMPA), a lithium bis(trimethylsilyl)amide (LiHMDS) solution (117 mL, 1M in THF) was added dropwise at a temperature of −70° C. and stirred for 1 hour. After an aqueous solution of NH₄C was added to terminate the reaction, an organic layer obtained by extraction with ethyl acetate (EA) was dried with MgSO₄ and filtered. The residue obtained by depressurizing and concentrating a filtrate was separated and purified through silica gel column chromatography to obtain Compound A-2 (7.2 g, 29%). A generated compound was confirmed through NMR.

1H NMR (500 MHz, CDCl₃) δ 8.87 (d, 1H), 8.18 (d, 1H), 8.03 (t, 1H), 7.67 (t, 1H), 7.38 (d, 2H), 7.26 (d, 2H), 6.70 (dd, 1H), 5.75 (d, 1H), 5.26 (d, 1H), 3.72 (t, 2H)

### Synthesis of Compound A-1

Sodium hydride (NaH) (1.04 g, 25.8 mmol, 60% dispersion in mineral oil) (manufactured by Sigma-Aldrich Co. LLC) and 155 mL of THF were put into in an RBF, and 77 mL of ethanethiol (EtSH) was added thereto at a temperature of 0° C. After a solution was stirred for 10 minutes, Compound A-2 (4.0 g, 12.9 mmol) was additionally added thereto and stirred at room temperature for 20 hours. A solvent was removed (caution-stench of EtSH), 129 mL of water was added to dissolve a residue, and then an aqueous solution was cleaned five times with diethyl ether (Et₂O). After the cleaned aqueous solution was transferred to an RBF, an aqueous hydrogen peroxide (H₂O₂) solution (11.5 mL, 34.5%) was added thereto and stirred at room temperature for 20 hours. After NaHCO₃ (1.1 g, 12.9 mmol) was added to a reaction solution, water was removed by distillation under reduced pressure. The remaining salt was dissolved in 130 mL of ethanol (EtOH) and filtered. A filtrate was concentrated under reduced pressure to obtain Compound A-1 (2.9 g, 83%). A generated compound was confirmed through nuclear magnetic resonance (NMR).

1H NMR (500 MHZ, CD₃OD) δ 7.39 (d, 2H), 7.26 (d, 2H), 6.72 (dd, 1H), 5.76 (dd, 1H), 5.21 (dd, 1H), 3.51 (t, 2H)

### Synthesis of Monomer A

Compound A-1 (2.90 g, 15.1 mmol) and bis(4-fluorophenyl)(phenyl)sulfonium bromide (5.73 g, 15.1 mmol) were put into an RBF, mixed with 26 mL of DCM and 4.4 ml of water, and then stirred for 3 hours. Thereafter, an organic layer was separated, dried with Na₂SO₄, and filtered, and then the residue obtained by concentrating a filtrate was separated and purified through silica gel column chromatography to obtain Monomer A (5 g, 60%). A generated compound was confirmed through NMR and liquid chromatography-mass spectrometry (LC-MS).

1H NMR (500 MHZ, CD₂Cl₂) δ 7.81 (m, 5H), 7.77-7.66 (m, 4H), 7.48-7.40 (m, 4H), 7.39-7.34 (m, 2H), 7.27 (d, 2H), 6.72 (dd, 1H), 5.74 (dd, 1H), 5.23 (dd, 1H), 3.51 (t, 2H). MS (ESI−) m/z 247.0797, MS(ESI+) m/z 300.0851.

### (2) Synthesis of Polymer 1

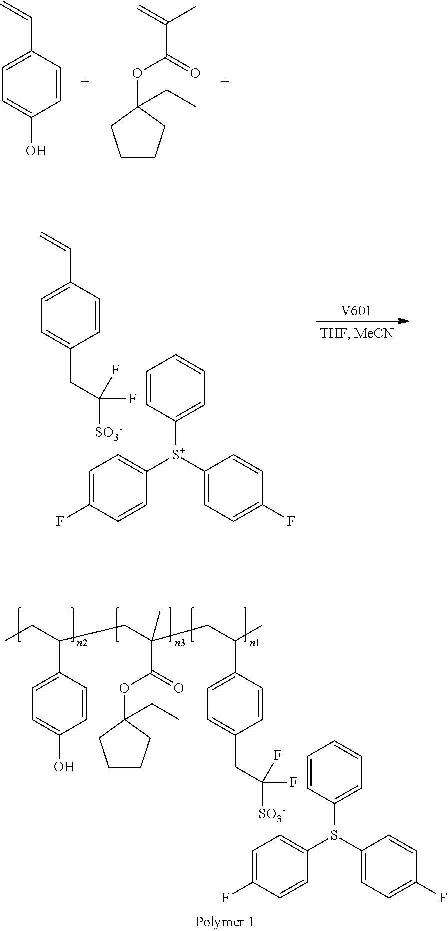

P-hydroxystyrene (0.5 g, 4.2 mmol), 1-ethylcyclopentyl methacrylate (0.95 g, 5.2 mmol), PAG monomer A (0.57 g, 1.0 mmol), V601 (dimethyl 2,2′-azobis(2-methylpropionate)) (0.12 g, 0.5 mmol) was put into a vial and dissolved in 6 mL of a solvent of THF and acetonitrile (ACN) (v/v of 50/50). A reaction was performed at a temperature of 70° C. for 24 hours, and Polymer 1 was synthesized by precipitation in diethyl ether.

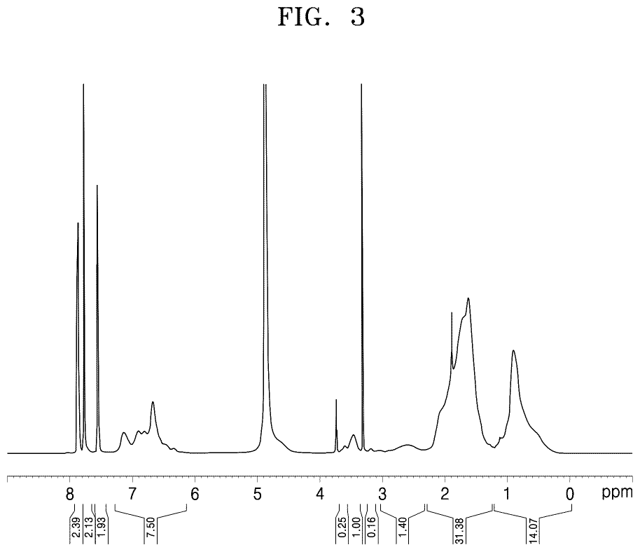

A result of 1H-NMR (CD₃OD) analysis of synthesized Polymer 1 is shown in FIG. 3.

### Evaluation Example 1: Evaluation of Acid Generation

10 wt % of an HS/ECPMA polymer (Mw of about 5 k) and 0.65 wt % of Coumarin 6 (C6) were dissolved in cyclohexanone, and each of photoacid generators of Table 1 below was added in the same number of moles as Coumarin 6 to obtain a mixed solution of each of Comparative Example 1 and Comparative Example 2.

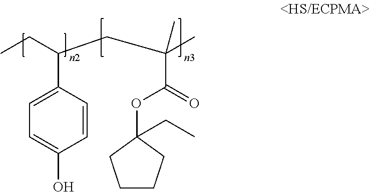

A mixed solution of Example 1 was formed by dissolving 10 wt % of Polymer 1 and 0.65 wt % of Coumarin 6 instead of an HS/ECPMA polymer and a photoacid generator.

Each of the mixed solutions of Example 1, Comparative Example 1, and Comparative Example 2 was applied to a thickness of 400 nm on 1 inch quartz through spin coating and dried at a temperature of 130° C. for 2 minutes to form a thin film. After the thin film was exposed to DUV rays (248 nm) at a dose of 10 mJ/cm² to 100 mJ/cm², absorbance was measured.

Acid generation increases the absorbance of Coumarin 6 at a wavelength of 535 nm, and when intensity upon exposure at 100 mJ is assumed to be intensity when 100% of Coumarin 6, which is an acid indicator, is converted, intensity upon exposure at 200 mJ is normalized, and thus degrees of acid generation in respective thin films are compared and shown in Table 1 below.

TABLE 1

| | Photoacid | Absorbance | Absorbance | C6 conversion |
|---|---|---|---|---|
| | generator | @DUV 20 mJ | @DUV 100 mJ | (%) @DUV 20 mJ |
| Example 1 | Polymer 1 | 1.11 | 1.28 | 86.6 |
| Comparative | PAG1 | 0.65 | 1.05 | 62.4 |
| Example 1 | | | | |
| Comparative | PAG2 | 0.46 | 0.94 | 48.9 |
| Example 2 | | | | |

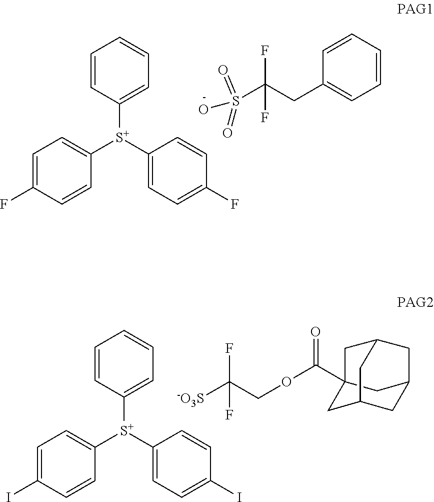

Referring to Table 1, it could be seen that the photoreactive polymer compound according to an embodiment exhibited an excellent acid generating effect as compared with the photoacid generators of Comparative Example 1 and Comparative Example 2.

### Evaluation Example 2: Evaluation of ADL and Surface Roughness (Rq)

### (ADL Evaluation)

An ADL was measured using a method described in Macromolecules, 43(9)4275 (2010). Specifically, the ADL was evaluated as follows.

First, a PR solution of Example 2 was prepared by mixing 70 mol % of PDQ1 below as a PDQ with respect to a content of a first repeating unit of Polymer 1.

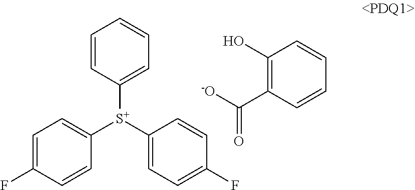

For a comparative group, a HS/ECPMA polymer was mixed with a photoacid generator shown in Table 2 below in the same number of moles as the first repeating unit of Polymer 1 and 70 mol % of a PDQ, and each mixture was dissolved in a mixed solution of PGME/PGMEA with a ratio of 7/3 wt/wt to prepare a PR solution of each of Comparative Example 3 and Comparative Example 4. Hereinafter, the first repeating unit of Polymer 1 and the photoacid generator shown in Table 2 are collectively referred to as PAG.

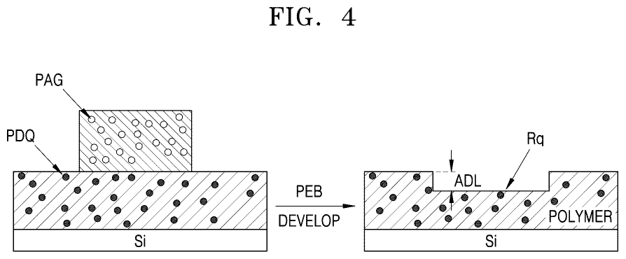

Each of the PR solutions of Example 2, Comparative Example 3, and Comparative Example 4 was applied to a thickness of about 80 nm on a PDMS substrate hydrophilicized by a UVO cleaner and exposed to DUV rays (248 nm) at a dose of 250 mJ/cm², thereby allowing an acid to be generated from the PAG. Then, the PDMS substrate coated with a polymer thin film including the PAG was placed on a Si wafer coated with a thin film of the same composition, and pressure was applied to adsorb the PDMS substrate (see FIG. 4).

Afterwards, when the PDMS substrate is separated, the polymer thin film in which a photoacid is generated by receiving light is transferred onto the Si wafer coated with an unexposed thin film. The Si substrate was placed on a hot plate and subjected to a heat treatment process at a temperature of 90° C. for 60 seconds to allow an acid of an exposed acid to diffuse into a lower unexposed thin film layer. After that, a developing process was performed with a 2.38 wt % TMAH aqueous solution. An ADL is confirmed by measuring and comparing a thickness of a first coated film and a thickness after the developing process on a finally obtained substrate, and values thereof are shown in Table 2.

### (Rq Evaluation)

In samples of which an ADL was evaluated, a surface of a first film newly exposed due to a TMAH phenomenon was observed through an atomic force microscope (AFM), and Rq was calculated from an average value of observed heights. Results thereof are shown in Table 2 below. In addition, AFM images obtained by observing Example 2 and Comparative Example 4 are shown in FIG. 5.

TABLE 2

| | Polymer | PAG | ADL (nm) | Rq (nm) |
|---|---|---|---|---|
| Example 2 | Polymer 1 | | 0 | 0.57 |
| Comparative Example 3 | HS/ECPMA | PAG1 | 89.4 | — |
| Comparative Example 4 | HS/ECPMA | PAG2 | 3.7 | 0.82 |

In Table 2, in the case of Comparative Example 3, since the ADL was excessively long, the lower unexposed thin film layer was entirely removed, and thus a surface of the Si wafer was exposed. Accordingly, Rq could not be measured.

Referring to Table 2, it could be seen that the photoreactive polymer compound according to an embodiment had significantly shorter ADL and lower Rq as compared with Comparative Example 3 and Comparative example 4.

### Evaluation Example 3: Etch Resistance Evaluation

In order to confirm the etch resistance characteristics of a synthesized polymer, a thickness change of a polymer thin film was observed in the following way. As a PR solution, the PR solutions of Example 2, Comparative Example 3, and Comparative Example 4 in Evaluation Example 2 were used. After the PR solution was applied onto a silicon wafer, spin coating was performed, and the RP solution was dried at a temperature of 130° C. for 1 minute to form a thin film with a thickness of 50 nm to 60 nm. Substrates coated with the thin films were etched for 5, 10, 20, and 30 seconds using RIE equipment (a mixed gas of CF₄ (20 sccm)/O₂ (5 sccm), an air pressure of 30 mtorr air pressure, and a condition of 50 W), respectively, and then thicknesses of the remaining thin films were measured. A relative etch rate was calculated through a relationship between an etching time and an etched thickness. Evaluation results thereof are shown in Table 3.

TABLE 3

| | | | Etch rate | Relative etch rate |
|---|---|---|---|---|
| | Polymer | PAG | (nm/s) | (relative value) |
| Example 2 | Polymer 1 | | 1.046 | 100 |
| Comparative | HS/ECPMA | PAG1 | 1.023 | 97.8 |
| Example 3 | | | | |
| Comparative | HS/ECPMA | PAG2 | 1.152 | 110.1 |
| Example 4 | | | | |

Referring to Table 3, it could be seen that the photoreactive polymer compound according to an embodiment had an etch rate slower than or equal to that of Comparative Example 3 and Comparative Example 4.

The photoreactive polymer compound according to an embodiment may have improved etch resistance, and an ADL of a photoacid generating group may be reduced. Accordingly, the photoresist composition according to an embodiment may have excellent characteristics such as improved developability and/or improved resolution.

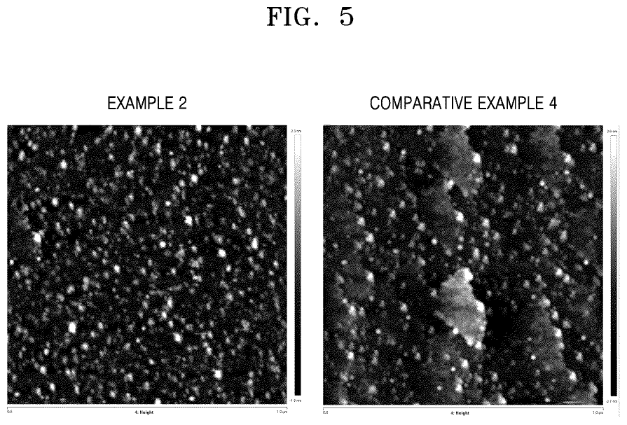

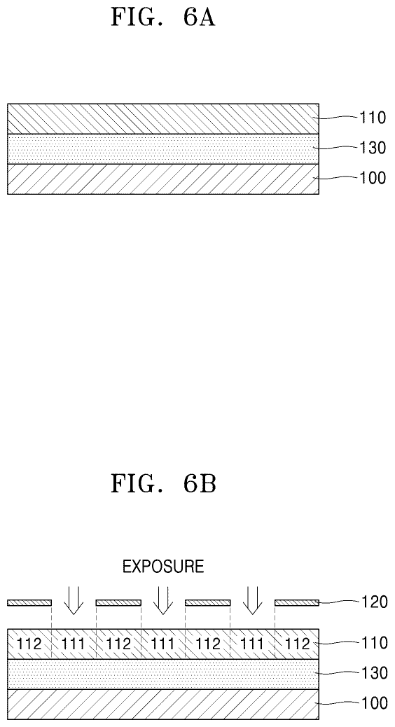

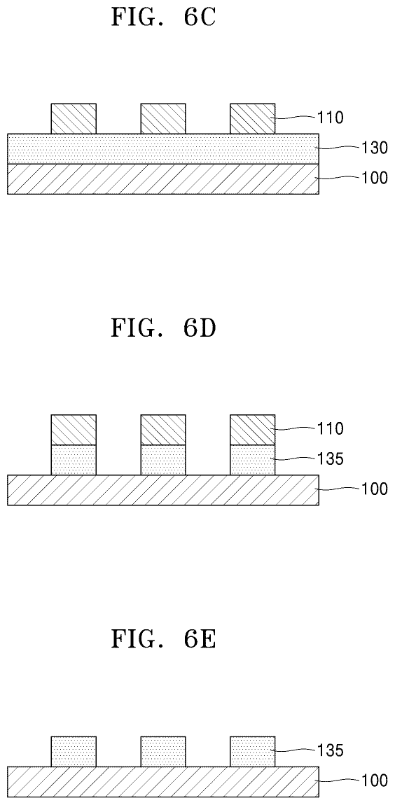

FIGS. 6A to 6E are side cross-sectional views illustrating a method of forming a patterned structure according to an embodiment.

Referring to FIG. 6A, a material layer 130 may be formed on the substrate 100 before forming a resist film 110 on the substrate 100. The resist film 110 may be formed on top of the material layer 130. A photoresist composition according to example embodiments may be applied to a desired thickness on the substrate 100, specifically, through a coating method, to form a photoresist film 110. The material layer 130 may include an insulating material (e.g., silicon oxide, silicon nitride), a semiconductor material (e.g., silicon), a metal (e.g., copper). In some embodiments, the material layer 130 may be a multi-layer structure. A material of the material layer 130 may be different than a material of the substrate 100.

Referring to FIG. 6B, the resist film 110 may undergo a pre-exposure bake process and may be exposed with high energy rays through a mask 120, after which the resist film 110 may include exposed regions 111 and unexposed regions 112.

Referring to FIG. 6C, the exposed resist film 110 may be developed using a developer (e.g., developing solution). The exposed area 111 may be washed away by the developer, whereas the unexposed area 112 may remain without being washed away by the developer.

Referring to FIG. 6D, exposed areas of the material layer 130 may be etched using the resist pattern 110 as a mask to form a material pattern 135 on the substrate 100.

Referring to FIG. 6E, the resist pattern 110 may be removed.

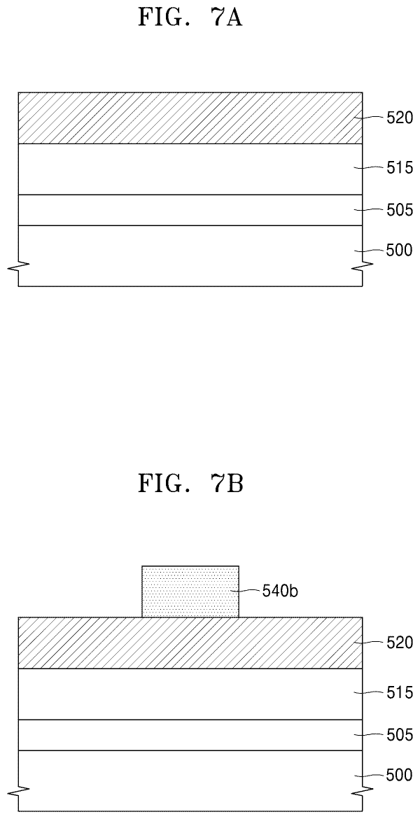

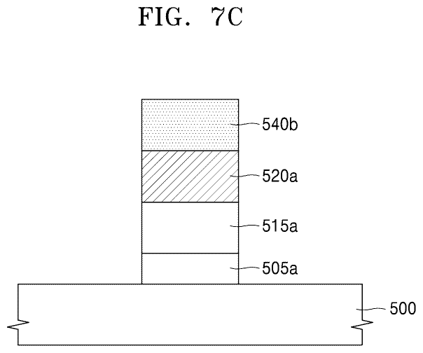

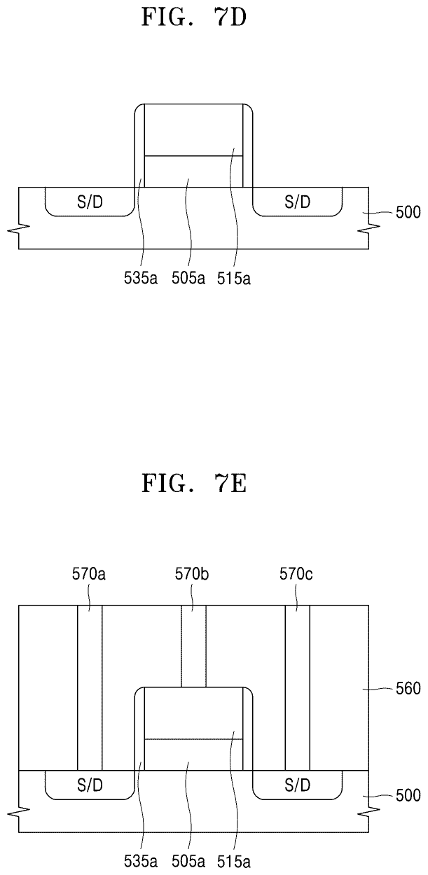

FIGS. 7A to 7E are side cross-sectional views illustrating a method of forming a semiconductor device according to an embodiment.

Referring to FIG. 7A, a gate dielectric 505 (e.g., silicon oxide) may be formed on a substrate 500. The substrate 500 may be a semiconductor substrate, such as a silicon substrate. A gate layer 515 (e.g., doped polysilicon) may be formed on the gate dielectric 505. A hardmask layer 520 may be formed on the gate layer 515.

Referring to FIG. 7B, a resist pattern 540b may be formed on the hardmask layer 520. The resist pattern 540b may be formed using a photoresist composition according to example embodiments. The photoresist composition may include a photoacid generator, an organic solvent, a base resin, and a photodegradable quencher.

Referring to FIG. 7C, the gate layer 515 and the gate dielectric 505 may be etched to form a hardmask pattern 520a, a gate electrode pattern 515a, and a gate dielectric pattern 505a.

Referring to FIG. 7D, a spacer layer may be formed over the gate electrode pattern 515a and the gate dielectric pattern 505a. The spacer layer may be formed using a deposition process (e.g., CVD). The spacer layer may be etched to form spacers 535a (e.g., silicon nitride) on sidewalls of the gate electrode pattern 515a and the gate dielectric pattern 505a. After forming the spacers 535a, ions may be implanted into the substrate 500 to form source/drain impurity regions S/D.

Referring to FIG. 7E, an interlayer insulating layer 560 (e.g., oxide) may be formed on the substrate 500 to cover the gate electrode pattern 515a, gate dielectric pattern 505a, and spacers 535a. Then, electrical contacts 570a, 570b, and 570c may be formed in the interlayer insulating layer 560 to connect to the gate electrode 515a and the S/D regions. The electrical contacts may be formed of a conductive material (e.g., metal). Although not illustrated, a barrier layer may be formed between sidewalls of the interlayer insulating layer 560 and the electrical contacts 570a, 570b, and 570c. While FIGS. 7A to 7E illustrate an example of forming a transistor, inventive concepts are not limited thereto. A resist composition including an organic salt according to one or more embodiments may be used in a patterning process to form other types of semiconductor devices. The resist composition may include a photoacid generator and an organic solvent.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A photoreactive polymer compound comprising:
a first repeating unit represented by Formula 1 below, 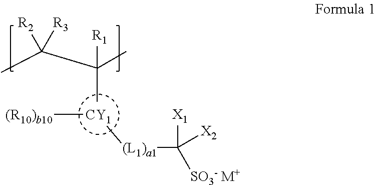
wherein, in Formula 1,
CY₁ is a cyclic C₁-C₃₀ hydrocarbon group optionally comprising a heteroatom,
L₁ is a single bond, or a divalent linking group which does not comprise oxygen,
a1 is 1, 2, 3, 4, 5, or 6,
X₁ and X₂ are each independently —F, or a linear, branched, or cyclic C₁-C₂₀ monovalent hydrocarbon group substituted with —F,
R₁ to R₃ and R₁₀ are each independently hydrogen, deuterium, a halogen, a cyano group, a hydroxy group, a linear, branched, or cyclic C₁-C₂₀ monovalent hydrocarbon group optionally comprising a heteroatom, or —N(Q₁)(Q₂),
Q₁ and Q₂ are each independently hydrogen, deuterium, or a linear, branched, or cyclic C₁-C₂₀ monovalent hydrocarbon group optionally comprising a heteroatom, an adjacent two or more of R₁ to R₃ and R₁₀ are optionally bonded to each other to form a cyclic C₁-C₃₀ hydrocarbon group optionally comprising a heteroatom,
b10 is 1, 2, 3, 4, 5, 6, 7, 8, 9, or 10, and
M⁺ is a counter cation.

2. The photoreactive polymer compound of claim 1, wherein CY₁ is a C₃-C₂₀ cycloalkyl group, a C₃-C₂₀ heterocycloalkyl group, a C₃-C₂₀ cycloalkenyl group, a C₃-C₂₀ heterocycloalkenyl group, a C₆-C₂₀ aryl group, or a C₁-C₂₀ heteroaryl group.

3. The photoreactive polymer compound of claim 1, wherein L₁ is a C₁-C₂₀ alkylene group, a C₃-C₂₀ cycloalkylene group, a C₆-C₂₀ arylene group, or a C₃-C₂₀ heteroarylene group, unsubstituted or substituted with deuterium, a halogen, a C₁-C₂₀ alkyl group, or any combination thereof.

4. The photoreactive polymer compound of claim 1, wherein X₁ and X₂ are each independently —F, —CH₂F, —CHF₂, or —CF₃.

5. The photoreactive polymer compound of claim 1, wherein R₁ to R₃ and R₁₀ are each independently a C₁-C₂₀ alkyl group, a C₃-C₂₀ cycloalkyl group, a C₁-C₂₀ heterocycloalkyl group, a C₆-C₂₀ aryl group, or a C₃-C₂₀ heteroaryl group, unsubstituted or substituted with hydrogen, deuterium, a halogen, a hydroxyl group, a C₁-C₂₀ alkyl group, a C₁-C₂₀ alkoxy group, a C₅-C₂₀ cycloalkyl group, a C₆-C₂₀ aryl group, a C₆-C₂₀ aryloxy group, a C₃-C₂₀ heteroaryl group, or any combination thereof.

6. The photoreactive polymer compound of claim 1, wherein M⁺ is a substituted or unsubstituted sulfonium cation, a substituted or unsubstituted iodonium cation, a substituted or unsubstituted selenium cation, a substituted or unsubstituted tellurium cation, a substituted or unsubstituted ammonium cation, a substituted or unsubstituted phosphonium cation, or any combination thereof.

7. The photoreactive polymer compound of claim 1, wherein M⁺ is represented by any one of Formulas 2-1 to 2-3 below: 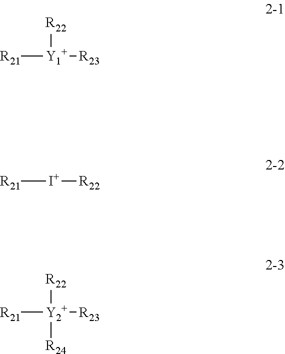
wherein, in Formulas 2-1 to 2-3,
Y₁⁺ is S⁺, Se⁺, or Te⁺,
Y₂⁺ is N⁺ or P⁺,
R₂₁ to R₂₄ are each independently a linear, branched, or cyclic C₁-C₃₀ monovalent hydrocarbon group optionally comprising a heteroatom, and
an adjacent two of R₂₁ to R₂₄ are optionally bonded to each other to form a ring.

8. The photoreactive polymer compound of claim 1, wherein the repeating unit represented by Formula 1 is represented by any one of Formulas 1-1 to 1-3 below: 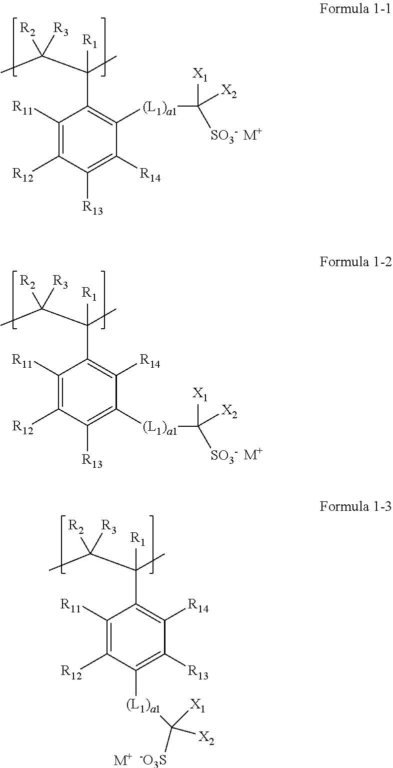
wherein, in Formulas 1-1 to 1-3,
L₁, a1, X₁, X₂, R₁ to R₃, and M⁺ are as defined in claim 1,
R₁₁ to R₁₄ are each independently defined as for R₁₀ in claim 1, and
an adjacent two or more of R₁₁ to R₁₄ are optionally bonded to each other to form a cyclic C₁-C₃₀ hydrocarbon group optionally comprising a heteroatom.

9. The photoreactive polymer compound of claim 1, wherein the first repeating unit is a photoacid generating unit.

10. The photoreactive polymer compound of claim 1, wherein the photoreactive polymer compound is a copolymer further comprising a second repeating unit represented by Formula 4 below or a third repeating unit represented by Formula 5 below: 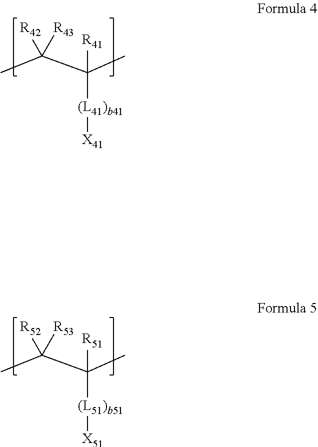
wherein, in Formulas 4 and 5,
L₄₁ and L₅₁ are each independently a single bond, a substituted or unsubstituted C₁-C₁₀ alkylene group, a substituted or unsubstituted C₃-C₁₀ cycloalkylene group, a substituted or unsubstituted C₃-C₁₀ heterocycloalkylene group, a substituted or unsubstituted phenylene group, a substituted or unsubstituted naphthylene group, *—O—*′, *—C(═O)O—*′, —OC(═O)—*′, *—C(═O)NH—*′, —NHC(═O)—*′, or any combination thereof,
b41 and b51 are each independently 1, 2, 3, 4, 5, or 6,
R₄₁ to R₄₃ and R₅₁ to R₅₃ are each independently hydrogen, deuterium, a halogen, a cyano group, a hydroxy group, a linear, branched, or cyclic C₁-C₂₀ monovalent hydrocarbon group optionally comprising a heteroatom, or —N(Q₁)(Q₂),
X₄₁ is hydrogen, deuterium, a halogen, a cyano group, a hydroxy group, a C₁-C₂₀ alkoxy group, a linear, branched, or cyclic C₁-C₂₀ monovalent hydrocarbon group optionally comprising a heteroatom, or —N(Q₁)(Q₂), and
X₅₁ is an acid labile group.

11. The photoreactive polymer compound of claim 10, wherein
the copolymer includes the second repeating unit represented by Formula 4, and
the second repeating unit represented by Formula 4 is a repeating unit represented by Formula 4-1 below: 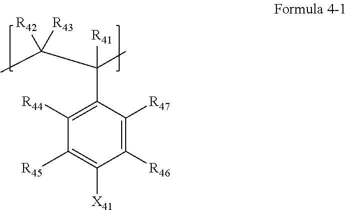
wherein, in Formula 4-1,
R₄₁ to R₄₃ and X₄₁ are as defined in Formula 4, and
R₄₄ to R₄₇ are each independently hydrogen, deuterium, a halogen, a cyano group, a hydroxy group, a C₁-C₂₀ alkoxy group, or a linear, branched, or cyclic C₁-C₂₀ monovalent hydrocarbon group optionally comprising a heteroatom.

12. The photoreactive polymer compound of claim 10, wherein
the copolymer includes the third repeating unit, and
the third repeating unit represented by Formula 5 is a repeating unit represented by Formula 5-1 below: 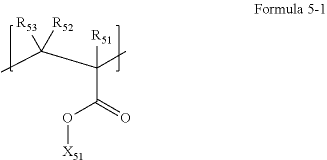
wherein, in Formula 5-1,
R₅₁ to R₅₃ and X₅₁ are as defined in Formula 5.

13. The photoreactive polymer compound of claim 10, wherein the acid labile group is a group represented by any one of Formulas 6-1 to 6-12 below: 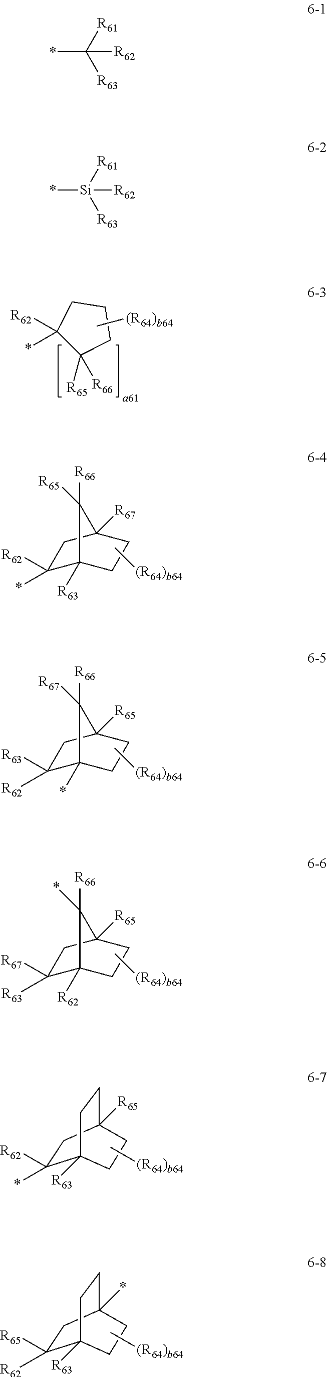 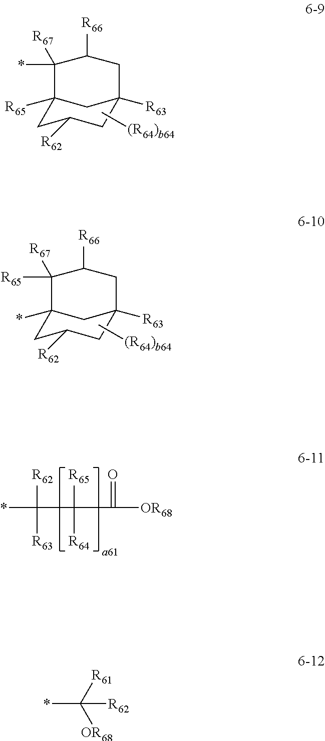
wherein, in Formulas 6-1 to 6-12,
a61 is an integer from 0 to 6,
R₆₁ to R₆₇ are each independently hydrogen, or a linear, branched, or cyclic C₁-C₂₀ monovalent hydrocarbon group optionally comprising a heteroatom,
R₆₈ is a linear, branched, or cyclic C₁-C₂₀ monovalent hydrocarbon group optionally comprising a heteroatom,
two or more of R₆₁ to R₆₈ are optionally bonded to each other to form a ring,
b64 is an integer from 0 to 6, and
* is a binding site with an adjacent atom.

14. The photoreactive polymer compound of claim 1, wherein the photoreactive polymer compound is represented by Polymer 1 below: 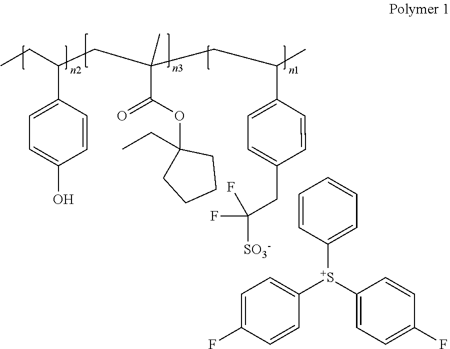
wherein, in Polymer 1,
n1, n2, and n3 are each independently an integer from 1 to 100,000.

15. A photoresist composition comprising:
the photoreactive polymer compound of claim 1.

16. The photoresist composition of claim 15, wherein
the photoresist composition comprises a photoacid generator, and
the photoacid generator consists of the photoreactive polymer compound.

17. The photoresist composition of claim 15, further comprising:
at least one of an organic solvent, a base resin, and a photodegradable quencher.

18. The photoresist composition of claim 15, wherein the photoresist composition does not comprise a base resin.

19. A method of forming a pattern, the method comprising:
applying the photoresist composition of claim 15 onto a substrate to form a photoresist film;
exposing at least a portion of the photoresist film to high-energy rays to provide an exposed photoresist film; and
developing the exposed photoresist film by using a developing solution.

20. The method of claim 19, wherein the exposing the at least a portion of the photoresist film is performed by irradiating at least one of ultraviolet (UV) rays, deep ultraviolet (DUV) rays, extreme ultraviolet (EUV) rays, or electron beams (EBs).
